(19) United States
(12) Patent Application Publication
(10) Pub. No.: US 2024/0014296 A1
(43) Pub. Date: Jan. 11, 2024

(54) SEMICONDUCTOR DEVICE AND SEMICONDUCTOR MODULE

(71) Applicant: Murata Manufacturing Co., Ltd., Kyoto-fu (JP)

(72) Inventors: Shigeki KOYA, Nagaokakyo-shi (JP); Masao KONDO, Nagaokakyo-shi (JP); Shaojun MA, Nagaokakyo-shi (JP); Satoshi GOTO, Nagaokakyo-shi (JP); Kenji SASAKI, Nagaokakyo-shi (JP); Takayuki TSUTSUI, Nagaokakyo-shi (JP); Kazuhito NAKAI, Nagaokakyo-shi (JP)

(73) Assignee: Murata Manufacturing Co., Ltd., Kyoto-fu (JP)

(21) Appl. No.: 18/474,088

(22) Filed: Sep. 25, 2023

Related U.S. Application Data
(63) Continuation of application No. PCT/JP2022/006454, filed on Feb. 17, 2022.

(30) Foreign Application Priority Data
Mar. 26, 2021 (JP) 2021-053563

(51) Int. Cl. H01L 29/737; H01L 29/06; H01L 27/082; H01L 29/417; H01L 29/423

(52) U.S. Cl. CPC H01L 29/737; H01L 29/0603; H01L 27/082; H01L 29/41708; H01L 29/42304

(57) ABSTRACT

In a semiconductor device, plural cells are disposed side by side on a substrate in a first direction. Each of the plural cells includes a bipolar transistor, an emitter electrode contained in a base layer of the bipolar transistor as viewed from above, and a base electrode. The bipolar transistors of the plural cells are connected in parallel with each other. Among the plural cells, the breakdown resistance of at least one second cell, which is other than a first cell disposed at each end, is higher than that of the first cell. It is possible to provide a semiconductor device that can reduce the deterioration of the breakdown resistance when flip-chip mounting is employed, as well as when face-up mounting is employed.

### CROSS-REFERENCE TO RELATED APPLICATIONS

This application claims benefit of priority to International Patent Application No. PCT/JP2022/006454, filed Feb. 17, 2022, and to Japanese Patent Application No. 2021-053563, filed Mar. 26, 2021, the entire contents of each are incorporated herein by reference.

### BACKGROUND

### Technical Field

The present disclosure relates to a semiconductor device including bipolar transistors and to a semiconductor module.

### Background Art

As a radio-frequency power amplifier for a mobile communication apparatus, a power amplifier including plural bipolar transistors, such as heterojunction bipolar transistors, connected in parallel with each other is used. A decline in the temperature uniformity between the plural bipolar transistors while operating may degrade the characteristics of the power amplifier and cause a breakdown in elements of the power amplifier. A semiconductor device that can enhance the temperature uniformity of plural bipolar transistors is disclosed in Japanese Unexamined Patent Application Publication No. 2005-353843. In the semiconductor device disclosed in Japanese Unexamined Patent Application Publication No. 2005-353843, among the plural bipolar transistors arranged in a line, the width of collector layers of bipolar transistors other than those positioned at both ends is wider than that of the other bipolar transistors. With this configuration, the heat dissipation of the bipolar transistors other than those at both ends to a substrate is enhanced, thereby improving the temperature uniformity.

### SUMMARY

The semiconductor device disclosed in Japanese Unexamined Patent Application Publication No. 2005-353843 achieves a sufficient effect of enhancing the temperature uniformity when the major heat dissipation path from the bipolar transistors reaches the substrate via the collector layers, that is, when face-up mounting is employed. However, when flip-chip mounting is employed for mounting the semiconductor device on the substrate, the major heat dissipation path does not pass through the substrate, thereby failing to achieve a sufficient effect of improving the temperature uniformity. The nonuniformity of the temperature deteriorates the breakdown resistance of the semiconductor device as a whole.

Accordingly, the present disclosure provides a semiconductor device and a semiconductor module that can reduce the deterioration of the breakdown resistance when flip-chip mounting is employed, as well as when face-up mounting is employed.

According to an aspect of the present disclosure, there is provided a semiconductor device including a substrate and plural cells disposed side by side on the substrate in a first direction. Each of the plural cells includes a bipolar transistor, at least one emitter electrode, and a base electrode. The bipolar transistor includes a collector layer, a base layer, and an emitter layer sequentially stacked on each other from the substrate. The at least one emitter electrode is contained in the base layer as viewed from above and is electrically connected to the emitter layer. The base electrode is contained in the base layer as viewed from above and is electrically connected to the base layer. The bipolar transistors of the plural cells are connected in parallel with each other. Among the plural cells, the breakdown resistance of at least one second cell, which is other than a respective first cell disposed at each end, is higher than the breakdown resistance of the first cell.

According to another aspect of the present disclosure, there is provided a semiconductor module including a semiconductor device and a module substrate. The semiconductor device includes a substrate, plural cells disposed side by side on the substrate in a first direction, and a conductive projection that is elongated in the first direction and that projects in a direction to separate from the substrate. The semiconductor device is flip-chip mounted on the module substrate via the conductive projection. Each of the plural cells includes a bipolar transistor and at least one emitter electrode. The bipolar transistor includes a collector layer, a base layer, and an emitter layer sequentially stacked on each other from the substrate. The at least one emitter electrode is contained in the base layer as viewed from above and is electrically connected to the emitter layer. The bipolar transistors of the plural cells are connected in parallel with each other. The conductive projection overlaps the plural cells as viewed from above and is electrically connected to the emitter electrodes of the plural cells. The module substrate includes a through-via that overlaps the conductive projection as viewed from above and that is elongated in the first direction and that is electrically connected to the conductive projection. The through-via includes an inward portion separated from both ends of the through-via in the first direction. The width of the inward portion is wider than the width of portions at both ends of the through-via.

A breakdown caused by a temperature rise is more likely to occur in a second cell other than first cells at both ends. The breakdown resistance of at least one second cell is higher than that of the first cells. It is thus possible to reduce the deterioration of the breakdown resistance of a semiconductor device as a whole even in a configuration in which a substrate is not part of a heat transfer path. The width of an inward portion of a through-via separated from both ends of the through-via in the first direction is wider than the portions at both ends of the through-via. The thermal resistance of the heat transfer path via the through-via is thus lowered in a region other than both ends of the through-via. This can relatively regulate a temperature rise of the cells other than those at both ends, thereby improving the breakdown resistance of the semiconductor device.

### BRIEF DESCRIPTION OF THE DRAWINGS

FIG. 1 is an equivalent circuit diagram of a semiconductor device according to a first embodiment;

FIG. 2 is a schematic plan view of two cells of the semiconductor device according to the first embodiment;

FIG. 3 is a sectional view taken along the long dashed dotted line 3-3 in FIG. 2;

FIG. 4 is a schematic plan view of part of a cell positioned at one end in a y direction among plural cells and part of one of plural cells other than the cells located at both ends;

FIG. 5 is a graph illustrating the measurement results of a safe operating area (SOA) boundary and a breakdown boundary;

FIG. 6 is a schematic plan view of part of a cell positioned at one end in they direction among plural cells of a semiconductor device of a second embodiment and part of one of plural cells other than the cells located at both ends;

FIG. 7 is a graph illustrating the measurement results of the SOA boundary;

FIG. 8 is a schematic plan view of part of a cell positioned at one end in they direction among plural cells of a semiconductor device of a third embodiment and part of one of plural cells other than the cells located at both ends;

FIG. 9 is a schematic plan view of part of a cell positioned at one end in they direction among plural cells of a semiconductor device according to a modified example of the third embodiment and part of two adjacent cells among plural cells other than the cells located at both ends;

FIG. 10 is a schematic plan view of part of a cell positioned at one end in the y direction among plural cells of a semiconductor device of a fourth embodiment and part of one of plural cells other than the cells located at both ends;

FIG. 11 is a schematic plan view of a semiconductor device according to a fifth embodiment;

FIG. 12 is a schematic plan view of a semiconductor device according to a sixth embodiment;

FIG. 13 is a schematic plan view of a semiconductor device according to a seventh embodiment; and

FIG. 14A is a plan view illustrating the arrangement of major components of a semiconductor device included in a semiconductor module of an eighth embodiment; FIG. 14B is a plan view illustrating the arrangement of major components of a module substrate included in the semiconductor module of the eighth embodiment; and FIGS. 14C and 14D are schematic sectional views of the semiconductor module of the eighth embodiment.

### DETAILED DESCRIPTION

### First Embodiment

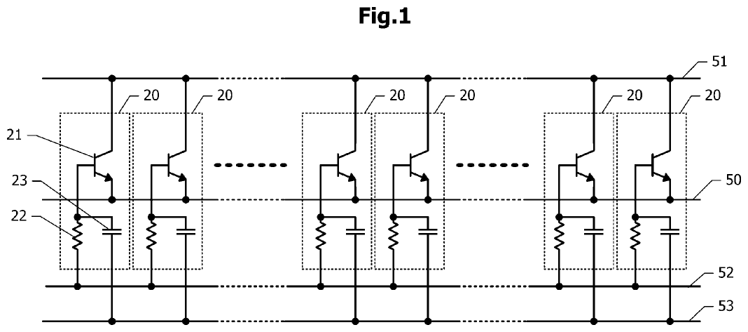

A semiconductor device according to a first embodiment will be described below with reference to FIGS. 1 through 5.

FIG. 1 is an equivalent circuit diagram of a semiconductor device according to the first embodiment. The semiconductor device of the first embodiment includes plural cells 20. The plural cells 20 are disposed side by side in one direction on a substrate so as to form a cell group. “The cells 20 are disposed side by side in one direction” does not necessarily mean that the cells 20 are arranged in one straight line, but the cells 20 may be arranged in a staggered form, for example. In FIG. 1, one cell disposed at each side of the cell group, two cells 20 each positioned inward of the cell 20 disposed at each side, and two cells 20 positioned at the center of the cell group are shown.

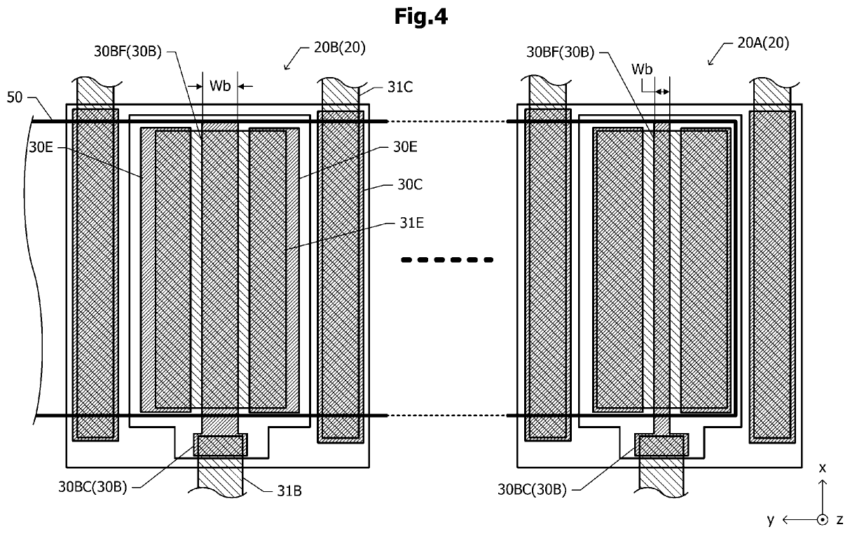

The plural cells 20 each include a bipolar transistor 21, a base ballast resistor element 22, and an input capacitor 23. The bipolar transistors 21 of the plural cells 20 are connected in parallel with each other. The emitter of each bipolar transistor 21 is connected to an emitter common line 50, while the collector of each bipolar transistor 21 is connected to a collector common line 51. The dimensions of the base electrodes of the bipolar transistors 21 in a plan view vary among the plural cells 20, which will be explained later with reference to FIG. 4.

The bipolar transistors 21 of the plural cells 20 are connected via the corresponding base ballast resistor elements 22 to a base bias line 52, which is used for all the cells 20, and are also connected via the corresponding input capacitors 23 to a radio-frequency signal input line 53, which is used for all the cells 20. A base bias current is supplied to the bipolar transistors 21 via the base bias line 52, which is used for all the cells 20, and via the base ballast resistor elements 22, which are provided for the respective cells 20. A radio-frequency signal is input into the bipolar transistors 21 via the radio-frequency signal input line 53 and the input capacitors 23, which are provided for the respective cells 20. The radio-frequency signal amplified by the bipolar transistors 21 is output from the collector common line 51. A collector voltage is applied to the bipolar transistors 21 via a choke coil and the collector common line 51.

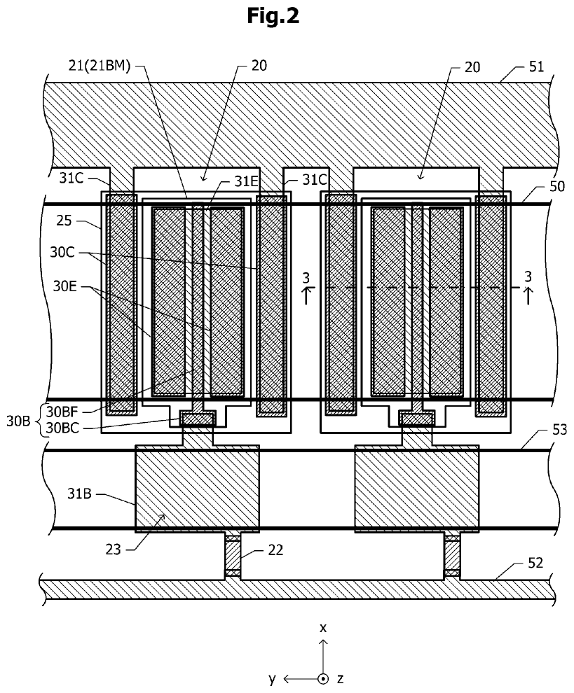

FIG. 2 is a schematic plan view of two cells 20 of the semiconductor device of the first embodiment. The plural cells 20 are disposed side by side in one direction. An xyz orthogonal coordinate system is defined in which the arranging direction of the plural cells 20 is the y direction and the direction normal to the surface of the substrate is the z direction. An n-type conductive sub-collector layer 25 is disposed on the front layer of the substrate. As viewed from above, a bipolar transistor 21 and a pair of collector electrodes 30C are contained in the sub-collector layer 25. The pair of collector electrodes 30C sandwich the bipolar transistor 21 in the y direction.

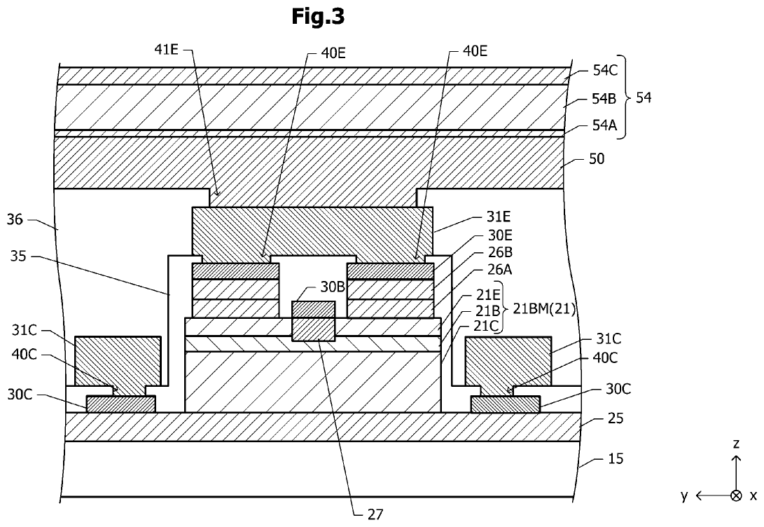

As will be explained later with reference to FIG. 3, the bipolar transistor 21 is constituted by a base mesa 21BM including a collector layer 21C, a base layer 21B, and an emitter layer 21E, which are stacked on the sub-collector layer 25 in this order. A pair of emitter electrodes 30E are disposed in the y direction with a space therebetween and a base electrode 30B is also disposed so that the pair of emitter electrodes 30E and the base electrode 30B are contained in the base mesa 21BM as viewed from above. Each of the emitter electrodes 30E has an elongated shape in the x direction, as viewed from above. The base electrode 30B includes a base finger 30BF having an elongated shape in the x direction and a base contact 30BC. The base finger 30BF is disposed between the pair of emitter electrodes 30E. The base contact 30BC is provided to continue to one end of the base finger 30BF.

In FIG. 2, the collector electrodes 30C, emitter electrodes 30E, and base electrode 30B are indicated by the hatched portion rising to the right. Conductive patterns in a first line layer are indicated by the relatively pale hatched portion falling to the right. In the first line layer, an emitter line 31E, collector lines 31C, a base line 31B, the collector common line 51, and the base bias line 52 are disposed.

The emitter line 31E extends from one emitter electrode 30E, crosses the base finger 30BF, and reaches the other emitter electrode 30E. The pair of emitter electrodes 30E are connected to each other by the emitter line 31E.

The plural collector lines 31C each overlap the corresponding collector electrode 30C as viewed from above and are each connected to the corresponding collector electrode 30C. The plural collector lines 31C extend to the outside of the sub-collector layer 25 toward one side of the x direction and continue to the collector common line 51.

The plural base lines 31B each overlap the corresponding base contact 30BC as viewed from above and are each connected to the base contact 30BC. The plural base lines 31B extend to the outside of the sub-collector layers 25 toward one side of the x direction and are connected to the base bias line 52 via the corresponding base ballast resistor elements 22.

In a second line layer, the emitter common line 50 and the radio-frequency signal input line 53 are disposed. The emitter common line 50 extends from the cell 20 at one end to the cell 20 at the other end in the y direction, as viewed from above, and is connected to the emitter line 31E provided for each cell 20. The radio-frequency signal input line 53 extends in the y direction to cross the base line 31B provided for each cell 20. The y-direction dimension of a portion of the base line 31B which overlaps the radio-frequency signal input line 53 is larger than the remaining portion of the base line 31B. The input capacitor 23 is formed in a region where the base line 31B and the radio-frequency signal input line 53 overlap each other.

FIG. 3 is a sectional view taken along the long dashed dotted line 3-3 in FIG. 2. The sub-collector layer 25 is disposed on a substrate 15. The base mesa 21BM is disposed on part of the sub-collector layer 25. The base mesa 21BM includes the collector layer 21C, the base layer 21B, and the emitter layer 21E stacked on each other from the sub-collector layer 25 in this order. The collector layer 21C, the base layer 21B, and the emitter layer 21E form the bipolar transistor 21. A pair of cap layers 26A are disposed in the y direction with a space therebetween on the emitter layer 21E. A contact layer 26B is disposed on each of the cap layers 26A.

Examples of the materials for the semiconductor layers will be discussed below. Semi-insulating GaAs is used for the substrate 15. The sub-collector layer 25 and the collector layer 21C are made of n-type GaAs. The base layer 21B is made of p-type GaAs. The emitter layer 21E is made of n-type InGaP. The cap layers 26A are made of n-type GaAs, while the contact layers 26B are made of n-type InGaAs.

The emitter electrodes 30E are disposed on the respective contact layers 26B. The emitter electrodes 30E are electrically connected to the emitter layer 21E via the corresponding contact layers 26B and cap layers 26A. Regions of the emitter layer 21E that overlap the cap layers 26A as viewed from above substantially function as emitter regions of the bipolar transistor 21.

By using the emitter electrodes 30E as an etching mask, unnecessary portions of the contact layers 26B and the cap layers 26A are removed by etching. This can form the contact layers 26B and the cap layers 26A in a self-alignment manner. The shapes of the contact layers 26B and the cap layers 26A in a plan view thus substantially match that of the emitter electrodes 30E in a plan view. After removing the unnecessary portions of the cap layers 26A and the contact layers 26B by etching, the emitter electrodes 30E may be formed by a lift-off process.

The base electrode 30B is disposed on the emitter layer 21E between the pair of cap layers 26A. The base electrode 30B is electrically connected to the base layer 21B via an alloyed region 27 which passes through the emitter layer 21E in the thickness direction and reaches the base layer 21B.

The collector electrodes 30C are disposed on the sub-collector layer 25 at the individual sides of the base mesa 21BM. The collector electrodes 30C are electrically connected to the collector layer 21C via the sub-collector layer 25.

An interlayer insulating film 35 is disposed on the entire region of the substrate 15 to cover some elements, such as the collector electrodes 30C, emitter electrodes 30E, and base electrode 30B. Emitter contact holes 40E and collector contact holes 40C are formed in the interlayer insulating film 35. On the interlayer insulating film 35, the emitter line 31E and the collector lines 31C are disposed. The emitter line 31E is connected to the emitter electrodes 30E by passing through the emitter contact holes 40E. The pair of emitter electrodes 30E are electrically connected to each other by the emitter line 31E. The collector lines 31C are connected to the corresponding collector electrodes 30C by passing through the collector contact holes 40C.

A second interlayer insulating film 36 is disposed on the interlayer insulating film 35 to cover the emitter line 31E and the collector lines 31C. An emitter contact hole 41E which is contained in the emitter line 31E as viewed from above is provided in the second interlayer insulating film 36. The emitter common line 50 is disposed on the interlayer insulating film 36. The emitter common line 50 is connected to the emitter line 31E by passing through the emitter contact hole 41E.

A protective film is disposed on the emitter common line 50. A cavity is formed in the protective film. The protective film is unseen in the cross section in FIG. 3 and the cavity is formed in the entire region on the emitter common line 50 in FIG. 3. A conductive projection 54 is disposed within the cavity of the protective film. The conductive projection 54 projects from the top surface of the protective film in a direction to separate from the substrate 15. In FIG. 2, the conductive projection 54 is not shown.

The conductive projection 54 includes an under bump metal layer 54A, a Cu pillar 54B, and a solder layer 54C stacked on each other from the emitter common line 50 in this order. The conductive projection 54 configured in this manner is called a Cu pillar bump. As the conductive projection 54, an Au bump, a solder ball bump, and a conductive column (post), for example, may be used instead of a Cu pillar bump.

FIG. 4 is a schematic plan view of part of a cell 20A positioned at one end in the y direction among the plural cells 20 and part of one of plural cells 20B other than the cells 20A located at both ends. The width Wb (y-direction dimension) of the base finger 30BF of the base electrode 30B is different between the cell 20A positioned at one end and at least one of the cells 20B other than the cells 20A at both ends. The width Wb of the base finger 30BF of the cell 20B is wider than that of the cell 20A. The dimensions of the emitter electrodes 30E of the cell 20A in a plan view and those of the cell 20B in a plan view are the same.

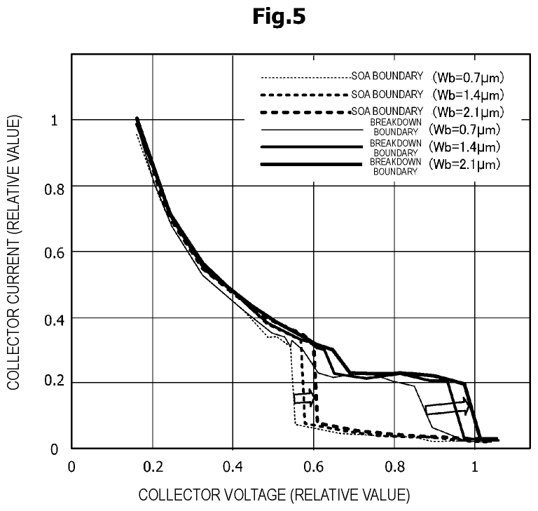

Advantages of the first embodiment will be described below with reference to FIG. 5.

Plural bipolar transistors were made by varying the width Wb of the base fingers 30BF and evaluation experiments were conducted to measure the SOA boundary and the breakdown boundary. FIG. 5 is a graph illustrating the measurement results of the SOA boundary and the breakdown boundary. The horizontal axis represents the collector voltage by the relative value, and the vertical axis represents the collector current by the relative value.

In the graph of FIG. 5, the broken lines indicate the SOA boundary, while the solid lines indicate the breakdown boundary. The region on the bottom left region of the graph from the SOA boundary is the safe operating area (SOA). When a combination of the collector voltage and the collector current exceeds the breakdown boundary, the bipolar transistor breaks down. The finest broken line and solid line indicate the measurement results of a sample whose width Wb of the base finger 30BF is 0.7 The second finest broken line and solid line indicate the measurement results of a sample whose width Wb of the base finger 30BF is 1.4 The thickest broken line and solid line indicate the measurement results of a sample whose width Wb of the base finger 30BF is 2.1 μm.

As indicated by the outline arrows in FIG. 5, increasing the width Wb of the base finger 30BF can enlarge the SOA and improve the breakdown resistance. Increasing the width Wb of the base finger 30BF in this manner achieves higher output and improved breakdown resistance of the bipolar transistors.

Regarding a semiconductor device in which the widths of the base fingers 30BF were the same for all cells 20, samples which were broken down were examined. It has been found that, among the plural cells 20, cells 20 other than those positioned at both ends, especially cells 20 near the central position, were mostly broken down. In the first embodiment, the shape of the base electrodes 30B of the cells 20 in a plan view is varied between the cells 20A at both ends and at least one of the cells 20B other than the cells 20A at both ends. This can enhance the breakdown resistance of the cells 20B to be higher than that of the cells 20A at both ends, thereby improving the breakdown resistance of the semiconductor device as a whole.

Increasing the width Wb of the base finger 30BF under the condition that the size of the emitter electrodes 30E is fixed enlarges the area of the base mesa 21BM, thereby increasing the base-collector junction capacitance. The increased base-collector junction capacitance decreases the gain (degrades the radio-frequency characteristics). In the first embodiment, the width Wb of the base fingers 30BF of the cells 20A at both ends is relatively made small, thereby reducing the deterioration of the gain of the semiconductor device as a whole.

In terms of improving the breakdown resistance, it is preferable to increase the number of cells 20B whose width Wb of the base finger 30BF is widened. However, increasing the number of such cells 20B considerably degrades the radio-frequency characteristics. The number of cells 20B whose width Wb of the base finger 30BF is widened is thus determined based on the required breakdown resistance and radio-frequency characteristics. Additionally, it is preferable to increase the width Wb of the base finger 30BF of a cell 20 which is particularly likely to break down.

Semiconductor devices according to modified examples of the first embodiment will now be described below.

In the first embodiment, the plural cells 20 are divided into two groups of cells 20 whose widths Wb of the base fingers 30BF are different from each other. However, the plural cells 20 may be divided into three or more groups of cells 20 whose widths Wb of the base fingers 30BF are different from each other. In this case, the width Wb of the base finger 30BF is increased in stages from the cells 20 at both ends toward the cell 20 at the central position.

Although in the first embodiment the widths Wb of the base fingers 30BF of the two cells 20A at both ends are equal to each other, they may be made different. Depending on the arrangement of plural cells 20 on a semiconductor substrate or other elements disposed near the plural cells 20, for example, the cell 20A at one end may be more likely to break down than the cell 20A at the other end. In this case, the width Wb of the base finger 30BF of the cell 20A which is more likely to break down is set to be wider than that of the other cell 20A.

In the first embodiment, the sub-collector layer 25 (FIG. 2) is provided for each cell 20. However, plural cells 20 may share one sub-collector layer 25. In this case, one collector electrode 30C may be disposed between two adjacent cells 20 and the two cells 20 may share the collector electrode 30C.

The semiconductor device of the first embodiment is flip-chip mounted on a module substrate via the conductive projection 54 (FIG. 3). As a modified example, the substrate 15 of the semiconductor device may be face-down mounted on a module substrate. In this case, too, the breakdown resistance of the semiconductor device as a whole can be improved by the enhanced breakdown resistance of the cells 20B.

### Second Embodiment

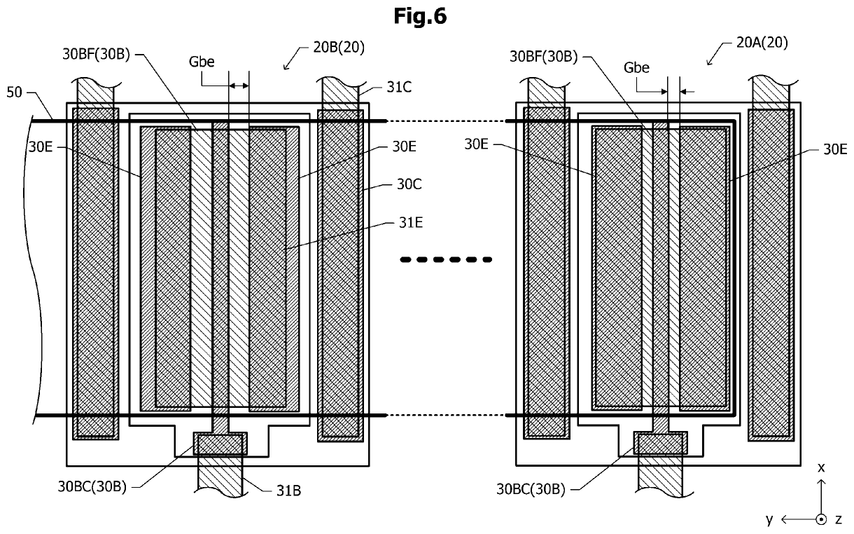

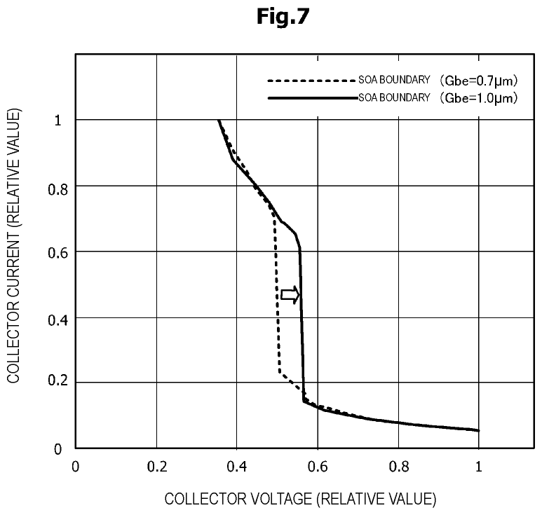

A semiconductor device according to a second embodiment will be described below with reference to FIGS. 6 and 7. An explanation of elements having the same configuration as those of the semiconductor device of the first embodiment discussed with reference to FIGS. 1 through 5 will be omitted.

FIG. 6 is a schematic plan view of part of a cell 20A positioned at one end in the y direction among plural cells 20 of the semiconductor device of the second embodiment and part of one of plural cells 20B other than the cells 20A located at both ends. In the first embodiment (FIG. 4), the shape of the base electrode 30B, that is, the width Wb of the base finger 30BF, is different between the cells 20A positioned at both ends and at least one of the cells 20B other than the cells 20A at both ends. In contrast, in the second embodiment, the width Wb of the base finger 30BF of the cells 20A at both ends and that of at least one cell 20B are the same, and the relative positional relationship between the base finger 30BF and the emitter electrodes 30E, for example, a gap Gbe in the y direction, is different between the cells 20A and at least one cell 20B. More specifically, the gap Gbe of at least one cell 20B other than the cells 20A at both ends is wider than that of the cells 20A.

Advantages of the second embodiment will be described below with reference to FIG. 7.

Plural bipolar transistors were made by varying the gap Gbe between the base finger 30BF and the emitter electrode 30E and evaluation experiments were conducted to measure the SOA boundary. FIG. 7 is a graph illustrating the measurement results of the SOA boundary. The horizontal axis represents the collector voltage by the relative value, and the vertical axis represents the collector current by the relative value. In the graph of FIG. 7, the broken line indicates the measurement results of the SOA boundary of a sample having a gap Gbe of 0.7 μm, while the solid line indicates the measurement results of the SOA boundary of a sample having a gap Gbe of 1.0 μm.

It is seen that increasing the gap Gbe can enlarge the SOA, as indicated by the outline arrow in FIG. 7.

Increasing the gap Gbe between the base finger 30BF and the emitter electrode 30E also improves the breakdown resistance. The reason why the breakdown resistance is improved will be explained below. A wider gap Gbe between the base finger 30BF and the emitter electrode 30E raises the base access resistance of the portion from the regions of the emitter layer 21E (FIG. 3) which substantially operate as the emitter to the base electrode 30B. An increased base current makes a voltage drop caused by the base access resistance in the cell 20B larger than that in the cell 20A.

Due to a larger voltage drop, the actual base voltage applied to the regions substantially operating as the emitter in the cell 20B becomes lower than that in the cell 20A. This relatively lowers the actual base-emitter voltage in the cell 20B, thereby relatively reducing the emitter current and the collector current. Hence, the density of a current flowing on the face of the emitter-base junction in the cell 20B becomes lower than that in the cell 20A. As a result, the breakdown resistance of the bipolar transistor 21 of the cell 20B is relatively improved.

The shape of the base electrodes 30B of all the plural cells is set to be the same, while the relative positional relationship between the base electrode 30B and the emitter electrode 30E is varied between the cells. Because of this difference in the relative positional relationship, the breakdown resistance of at least one of the cells 20B other than the cells 20A at both ends is made higher than that of the cells 20A. Accordingly, in the second embodiment, as well as in the first embodiment, the breakdown resistance of the semiconductor device as a whole can be enhanced.

Increasing the gap Gbe between the base finger 30BF and the emitter electrode 30E under the condition that the size of the emitter electrodes 30E is fixed enlarges the area of the base mesa 21BM, thereby increasing the base-collector junction capacitance. The increased base-collector junction capacitance decreases the gain. In the second embodiment, the gap Gbe between the base finger 30BF and the emitter electrode 30E in the cells 20A at both ends is relatively made smaller, thereby reducing the deterioration of the gain of the semiconductor device as a whole.

A modified example of the second embodiment will be described below.

In the second embodiment, the width Wb of the base finger 30BF of the cell 20A and that of the cell 20B is the same. As in the first embodiment (FIG. 4), however, the width Wb of the base finger 30BF of a cell 20B, which is other than the cells 20A at both ends, may be wider than that of the cells 20A. That is, the shape of the base electrode 30B in a plan view may be made different between the plural cells 20, and also, the relative positional relationship between the base electrode 30B and the emitter electrode 30E may be made different between the plural cells 20.

### Third Embodiment

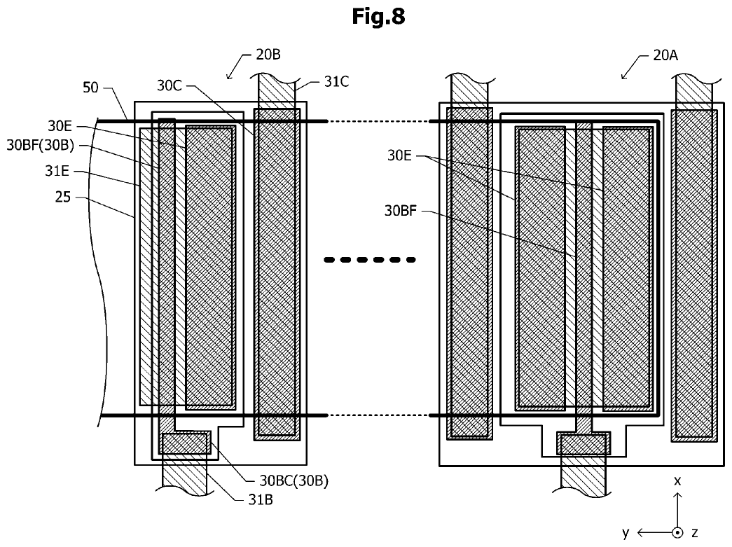

A semiconductor device according to a third embodiment will be described below with reference to FIG. 8. An explanation of elements having the same configuration as those of the semiconductor device of the first embodiment discussed with reference to FIGS. 1 through 5 will be omitted.

FIG. 8 is a schematic plan view of part of a cell 20A positioned at one end in the y direction among the plural cells 20 of the semiconductor device of the third embodiment and part of one of plural cells 20B other than the cells 20A at both ends.

In the first embodiment (FIG. 4), two emitter electrodes 30E are disposed in each of the cells 20. In contrast, in the third embodiment, although two emitter electrodes 30E are disposed in the cells 20A at both ends, only one emitter electrode 30E is disposed in at least one of the cells 20B. In the cell 20B, the base finger 30BF is located at one side of the emitter electrode 30E, while the collector electrode 30C is located at the other side of the emitter electrode 30E.

Advantages of the third embodiment will be discussed below.

In the configuration in which the base finger 30BF is disposed between two emitter electrodes 30E, as in the cells 20A at both ends, the distance from the base finger 30BF to one emitter electrode 30E and that from the base finger 30BF to the other emitter electrode 30E may become different due to an allowable level of misalignment occurring in the manufacturing process. The difference in the distance causes a current to concentrate on the emitter electrode 30E closer to the base finger 30BF than the other emitter electrode 30E, thereby making it likely to cause a breakdown. In the cell 20B including only one emitter electrode 30E, even with the occurrence of an allowable level of misalignment in the manufacturing process, the concentration of a current on the emitter electrode 30E disposed at one side does not occur. A decrease in the breakdown resistance caused by a misalignment is thus unlikely to occur.

In this manner, at least one of the cells 20B other than the cells 20A at both ends is configured so that a decrease in the breakdown resistance caused by a misalignment is unlikely to occur. This can reduce the occurrence of breakdown in the semiconductor device.

Using only one emitter electrode 30E in the cell 20B increases the ratio of the area of the base mesa 21BM to that of the emitter electrode 30E. This decreases the gain. In the third embodiment, the cells 20A at both ends each include two emitter electrodes 30E. This can reduce the deterioration of the gain of the semiconductor device.

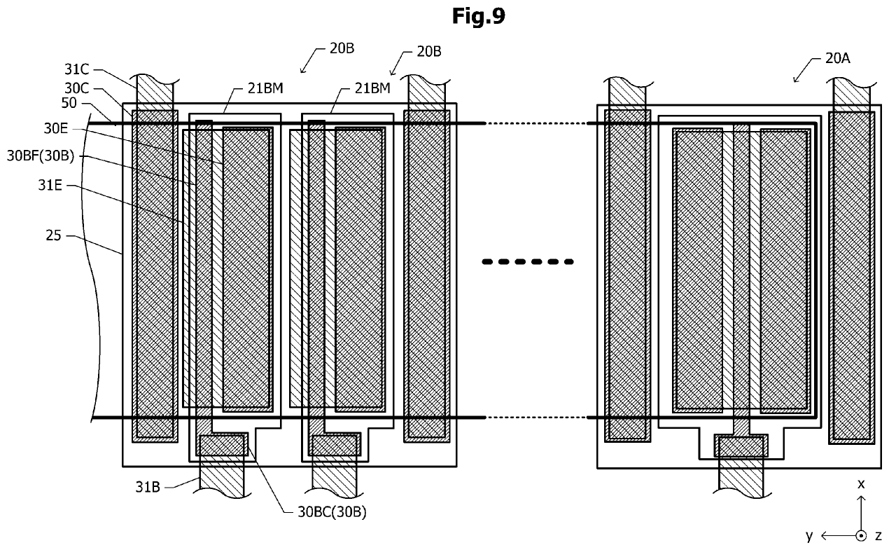

A semiconductor device according to a modified example of the third embodiment will be described below with reference to FIG. 9.

FIG. 9 is a schematic plan view of part of a cell 20A positioned at one end in the y direction among the plural cells 20 of the semiconductor device according to the modified example of the third embodiment and part of two adjacent cells 20B among the plural cells other than the cells 20A at both ends.

If plural cells 20B are provided in the third embodiment (FIG. 8), the positional relationships among the base finger 30BF, the emitter electrode 30E, and the collector electrode 30C are the same for the plural cells 20B. In contrast, in the modified example in FIG. 9, the positional relationships among the base finger 30BF, the emitter electrode 30E, and the collector electrode 30C are different between two adjacent cells 20B. More specifically, the base mesas 21BM of the two cells 20B are disposed between the collector electrodes 30C of the two cells 20B. The relative positional relationship between the base electrode 30B and the emitter electrode 30E within the base mesa 21BM of one cell 20B and that of the other cell 20B are the same. As viewed from above, the two cells 20B are contained in the sub-collector layer 25, which is provided for the two cells 20B.

As in this modified example, the positional relationships among the base finger 30BF, the emitter electrode 30E, and the collector electrode 30C may be different between plural cells 20B. As a result of two cells 20B sharing one sub-collector layer 25, the two cells 20B can be disposed close to each other.

### Fourth Embodiment

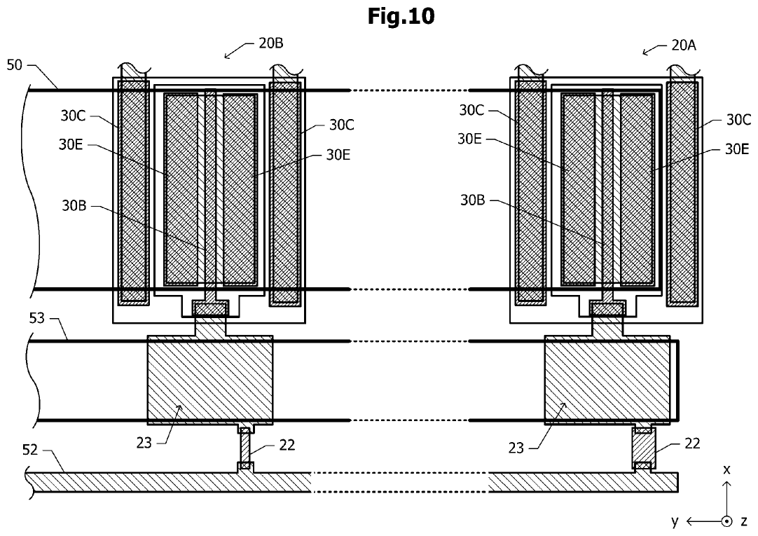

A semiconductor device according to a fourth embodiment will be described below with reference to FIG. 10. An explanation of elements having the same configuration as those of the semiconductor device of the first embodiment discussed with reference to FIGS. 1 through 5 will be omitted.

FIG. 10 is a schematic plan view of part of a cell 20A positioned at one end in the y direction among the plural cells 20 of the semiconductor device of the fourth embodiment and part of one of plural cells 20B other than the cells 20A at both ends. The shapes of the emitter electrodes 30E, the base electrode 30B, and the collector electrodes 30C of the cell and those of the cell 20B are the same. The relative positional relationships among the emitter electrodes 30E, the base electrode 30B, and the collector electrodes 30C of the cell 20A and those of the cell 20B are the same.

The resistance of the base ballast resistor element 22 of at least one of the cells 20B is higher than that of the cells 20A at both ends. For example, relatively decreasing the width of a high-resistance conductive pattern forming the base ballast resistor element 22 increases the resistance of the cell 20B.

Advantages of the fourth embodiment will be described below.

As explained in the first embodiment, one of the reasons why the cells 20 at the central position in the arranging direction (y direction) of the plural cells 20 are vulnerable to a breakdown may be that the cells 20 at the central position are more likely to reach high temperatures than the cells 20 at both ends. In the fourth embodiment, the resistance of the base ballast resistor element 22 of at least one of the cells 20B other than the cells 20A at both ends is made higher, so that thermal runaway is less likely to occur in the cell 20B than in the cells 20A at both ends. The cell 20B, which is more likely to reach high temperatures, is configured so that it is less likely to cause thermal runaway in the cell 20B than in the cells 20A at both ends. This can suppress the occurrence of thermal runaway of the semiconductor device, thereby improving the breakdown resistance.

Increasing the resistance of the base ballast resistor element 22 decreases the gain of the bipolar transistor 21. In the fourth embodiment, the resistance of the base ballast resistor elements 22 of the cells 20A at both ends is relatively lowered, thereby reducing the deterioration of the gain of the semiconductor device. The number and the positions of cells 20B for which the resistance of the base ballast resistor elements 22 is relatively increased are determined based on the required breakdown resistance and gain.

### Fifth Embodiment

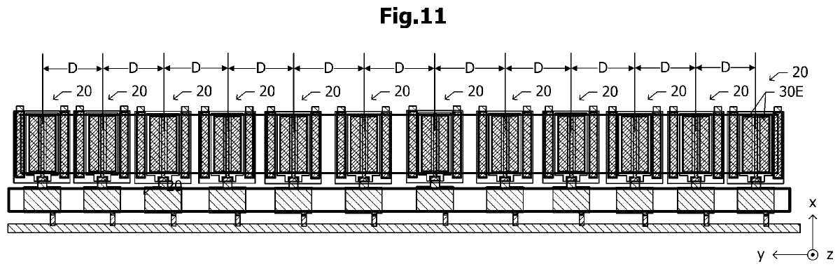

A semiconductor device according to a fifth embodiment will be described below with reference to FIG. 11. An explanation of elements having the same configuration as those of the semiconductor device of the first embodiment discussed with reference to FIGS. 1 through 5 will be omitted.

FIG. 11 is a schematic plan view of the semiconductor device of the fifth embodiment. In the first embodiment (FIG. 4), the shape of the base electrode 30B is different between the cells 20A at both ends and at least one of the cells 20B other than the cells 20A at both ends. In contrast, in the fifth embodiment, the shape of the base electrode 30B in a plan view is the same for all the cells 20. The relative positional relationship between the base electrode 30B and the emitter electrode 30E is also the same for all the cells 20.

In the fifth embodiment, the center-to-center distance D between adjacent cells 20 in the y direction is different among the cells 20. As the “center” of each cell 20, the centroid of each emitter electrode 30E of the cell 20 in a plan view is used. The center-to-center distance D between each of the cells 20 at both ends and its adjacent cell 20 in the y direction is narrower than that between two adjacent cells 20 other than the cells 20 at both ends. For example, the center-to-center distance D gradually becomes wider from the cells 20 at both ends toward the cell 20 at the center.

Advantages of the fifth embodiment will be described below.

In the configuration in which plural cells 20 are equally arranged in the y direction, the cells 20 near the center are more likely to reach high temperatures than the cells 20 at both ends. In the fifth embodiment, the center-to-center distance D in the y direction between two adjacent cells near the center is wider than that between each of the cells 20 at both ends and its adjacent cell 20. With this configuration, the temperature of the plural cells 20 arranged in the y direction becomes uniform. This regulates a temperature rise of a specific cell 20, thereby suppressing the occurrence of thermal runaway. This can improve the breakdown resistance of the semiconductor device.

A semiconductor device according to a modified example of the fifth embodiment will be discussed below.

In the fifth embodiment, the shape of the base electrode 30B in a plan view and the relative positional relationship between the base electrode 30B and the emitter electrode 30E are the same for all the cells 20. In an alternative configuration, as in the first embodiment (FIG. 4), the shape of the base electrode 30B in a plan view may be made different between the cells 20. Additionally, as in the second embodiment (FIG. 6), the third embodiment (FIG. 8), and the modified example of the third embodiment (FIG. 9), the relative positional relationship between the base electrode 30B and the emitter electrode may be made different between the plural cells 20.

### Sixth Embodiment

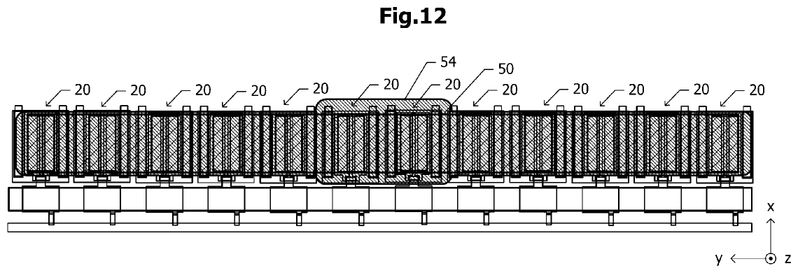

A semiconductor device according to a sixth embodiment will be described below with reference to FIG. 12. An explanation of elements having the same configuration as those of the semiconductor device of the fifth embodiment discussed with reference to FIG. 11 will be omitted.

FIG. 12 is a schematic plan view of the semiconductor device of the sixth embodiment. In the fifth embodiment (FIG. 11), the center-to-center distance D between adjacent cells 20 in the y direction is not constant. In the sixth embodiment, however, the center-to-center distance D between adjacent cells 20 in the y direction is constant. That is, the plural cells 20 are equally arranged in the y direction. The emitter common line 50 and the conductive projection 54 are disposed to overlap the plural cells 20, as viewed from above. In FIG. 12, the emitter common line 50 is indicated by the relatively pale hatched portion rising to the right, while the conductive projection 54 is indicated by the relatively dark hatched portion falling to the right.

As shown in FIG. 3, the conductive projection 54 is electrically connected to the emitter layer 21E of the bipolar transistor 21 via the emitter common line 50, emitter line 31E, emitter electrodes 30E, contact layers 26B, and cap layers 26A. The path electrically connecting the conductive projection 54 and the emitter layer 21E with each other also serves as a transfer path for heat generated in the bipolar transistor 21.

The conductive projection 54 has an elongated shape in they direction in a plan view and the width (x-direction dimension) of the central portion in the y direction is wider than that of the remaining portion.

Advantages of the sixth embodiment will be described below. The width of the central portion of the conductive projection 54, which serves as the heat transfer path, is wider than that of the remaining portion. With this configuration, the heat dissipation of the cell 20 at the central portion of the conductive projection 54 via the conductive projection 54 is higher than that of the cells 20 at both ends. The heat dissipation characteristics of the cell 20 positioned at the central portion of the conductive projection 54, which is likely to reach high temperatures, are relatively enhanced, thereby improving the uniformity of the temperatures of the plural cells 20. This regulates a temperature rise of a specific cell 20, thereby suppressing the occurrence of thermal runaway. This can improve the breakdown resistance of the semiconductor device.

A semiconductor device according to a modified example of the sixth embodiment will be described below.

In the sixth embodiment, the shape of the base electrode 30B in a plan view and the relative positional relationship between the base electrode 30B and the emitter electrode 30E are the same for all the cells 20. However, at least one of the shape of the base electrode 30B in a plan view and the relative positional relationship between the base electrode 30B and the emitter electrode 30E may be made different between the cells 20.

For example, in the first embodiment, a portion of the conductive projection 54 which overlaps the cell 20B (FIG. 4) having a relatively large width Wb of the base finger 30BF may be made relatively wide. In the second embodiment, a portion of the conductive projection 54 which overlaps the cell 20B (FIG. 6) having a relatively large gap Gbe between the base finger 30BF and the emitter electrode 30E may be made relatively wide. In the third embodiment, a portion of the conductive projection 54 which overlaps the cell 20B (FIG. 8) including only one emitter electrode 30E may be made relatively wide.

### Seventh Embodiment

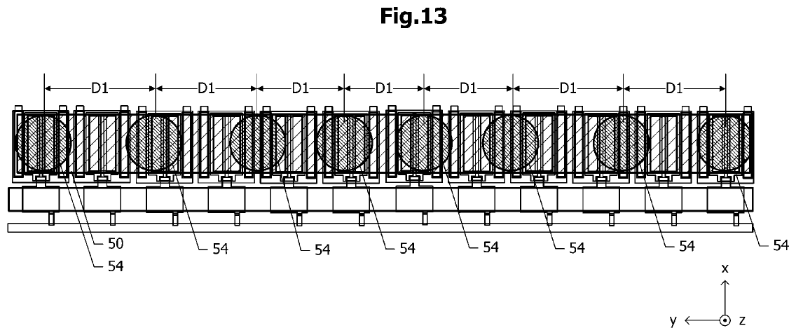

A semiconductor device according to a seventh embodiment will be described below with reference to FIG. 13. An explanation of elements having the same configuration as those of the semiconductor device of the sixth embodiment discussed with reference to FIG. 12 will be omitted.

FIG. 13 is a schematic plan view of the semiconductor device of the seventh embodiment. In the sixth embodiment (FIG. 12), one conductive projection 54 elongated in the y direction is disposed. In contrast, in the seventh embodiment, plural conductive projections 54 are arranged in the y direction in a cell distribution region where the plural cells 20 are arranged from the cell 20 at one end to the cell at the other end as viewed from above. The shape of each of the plural conductive projections 54 in a plan view is circular, for example. The areas of the plural conductive projections 54 are the same. The shape of each of the conductive projections 54 in a plan view may be a rounded square or a rounded rectangle, for example.

The distribution density of the plural conductive projections 54 becomes higher from the end portions of the cell distribution region toward the center thereof in the y direction. For example, the center-to-center distance D1 between the centroids of two adjacent conductive projections 54 is not uniform and the center-to-center distance D1 near the center in the y direction is narrower than that near the end portions.

Advantages of the seventh embodiment will be described below.

In the seventh embodiment, the distribution density of the conductive projections 54 near the central portion of the cell distribution region is higher than that of the conductive projections 54 near the end portions. Hence, the heat dissipation from the cells 20 near the center via the conductive projection 54 is higher than that from the cells 20 at the end portions. The temperature uniformity of the plural cells 20 can thus be improved, as in the sixth embodiment (FIG. 12). This regulates a temperature rise of a specific cell 20, thereby suppressing the occurrence of thermal runaway. This can improve the breakdown resistance of the semiconductor device.

A semiconductor device according to a modified example of the seventh embodiment will be discussed below. In the seventh embodiment, the shape of the base electrode 30B in a plan view and the relative positional relationship between the base electrode 30B and the emitter electrode 30E are the same for all the cells 20. As a modified example, however, the shape of the base electrode 30B in a plan view and the relative positional relationship between the base electrode 30B and the emitter electrode 30E may be made different between the cells 20. For example, the conductive projections 54 of the semiconductor device according to the seventh embodiment may be used as the conductive projections 54 of the semiconductor devices according to the first embodiment discussed with reference to FIGS. 1 through 5, the second embodiment discussed with reference to FIGS. 6 and 7, and the third embodiment discussed with reference to FIG. 8.

### Eighth Embodiment

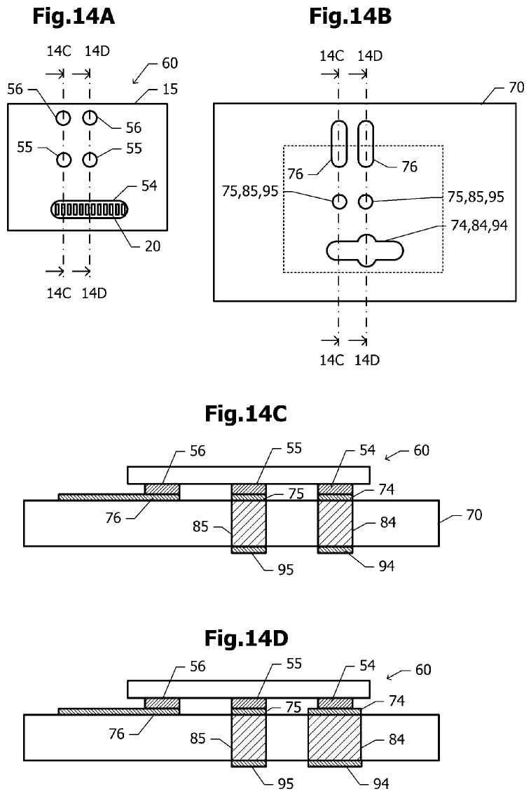

A semiconductor module according to an eighth embodiment will be described below with reference to FIGS. 14A through 14D. The semiconductor module according to the eighth embodiment includes the semiconductor device of the first embodiment discussed with reference to FIGS. 1 through 5 and a module substrate on which this semiconductor device is mounted.

FIG. 14A is a plan view illustrating the arrangement of major components of a semiconductor device 60 included in the semiconductor module of the eighth embodiment. On a substrate 15, plural cells 20 and a conductive projection 54 overlapping the plural cells 20 as viewed from above are arranged. The conductive projection 54 is electrically connected to the emitter layer 21E of the cell 20, as shown in FIG. 3. In addition to the conductive projection 54, ground conductive projections 55 and signal input/output conductive projections 56 are provided.

FIG. 14B is a plan view illustrating the arrangement of major components of a module substrate 70 included in the semiconductor module of the eighth embodiment. On the top surface of the module substrate 70, lands 74, 75, and 76 are provided. Through-vias 84 and 85 are formed so as to substantially match the lands 74 and 75, respectively, as viewed from above. On the bottom surface of the module substrate, external connection terminals 94 and 95 are provided.

FIGS. 14C and 14D are schematic sectional views of the semiconductor module according to the eighth embodiment. The semiconductor device 60 is flip-chip mounted on the module substrate 70. FIG. 14C is a sectional view taken along the long dashed dotted line 14C-14C in FIGS. 14A and 14B. FIG. 14D is a sectional view taken along the long dashed dotted line 14D-14D in FIGS. 14A and 14B.

The conductive projections 54, 55, and 56 of the semiconductor device 60 are connected to the lands 74, 75 and 76, respectively, on the module substrate 70 by soldering. The through-via 84 connects the land 74 on the top surface of the module substrate 70 and the external connection terminal 94 on the bottom surface of the module substrate 70 to each other. The other through-via 85 connects the land 75 on the top surface of the module substrate 70 and the external connection terminal 95 on the bottom surface of the module substrate 70 to each other. The external connection terminals 94 and 95 are connected to lands on a motherboard, for example.

The shape of the land 74 in a plan view is elongated in the arranging direction of the plural cells 20. The width of an inward portion of the land 74 separated from both ends in the longitudinal direction of the land 74 is wider than the portions at both ends of the land 74. In other words, the width of a range including the center of the land 74 in the longitudinal direction is wider than that of portions of the land 74 closer to both ends than this range. The shapes of the through-via 84 and the external connection terminal 94 in a plan view substantially match the shape of the land 74 in a plan view. The through-via 84 overlaps the conductive projection 54 of the semiconductor device 60 as viewed from above and is electrically connected to the conductive projection 54 via the land 74.

Advantages of the eighth embodiment will be described below.

The through-via 84 of the module substrate 70 serves to electrically connect the semiconductor device 60 and a motherboard to each other and also serves as a heat transfer path through which heat generated in the cells 20 of the semiconductor device 60 is transferred to the motherboard. In the eighth embodiment, the widths of the central portions of the land 74, through-via 84, and external connection terminal 94 are wider than the widths of the other portions of the land 74, through-via 84, and external connection terminal 94. Hence, the thermal resistance of the heat transfer path from the cells 20 near the center to the motherboard is lower than that from the cells 20 near both ends to the motherboard.

This can regulate a temperature rise of the cells 20 near the center compared with that of the cells 20 near both ends. Since the temperature rise of the cells 20 at the center, which are more likely to reach high temperatures, is regulated, the uniformity of the temperatures of the plural cells 20 can be enhanced. This regulates a temperature rise of a specific cell 20, thereby suppressing the occurrence of thermal runaway. This can improve the breakdown resistance of the semiconductor device.

A semiconductor module according to a modified example of the eighth embodiment will be described below.

In the semiconductor module according to the eighth embodiment, as the semiconductor device 60, the semiconductor device of the first embodiment discussed with reference to FIGS. 1 through 5 is used. However, the semiconductor device of the embodiment other than the first embodiment may be used. Alternatively, a semiconductor device in which the width Wb of the base finger 30BF is the same for all the cells 20, the relative positional relationship between the base electrode 30B and the emitter electrode 30E is the same for all the cells 20, and the plural cells 20 are equally arranged may be used as the semiconductor device 60 of the semiconductor module of the eighth embodiment.

### Ninth Embodiment

A semiconductor device according to a ninth embodiment will be described below. An explanation of elements having the same configuration as those of any of the semiconductor devices of the first through seventh embodiments will be omitted.

In the semiconductor devices of the first through seventh embodiments, one amplifier circuit is constituted by plural cells 20 connected in parallel with each other (the cells 20 in FIG. 1, for example). In a semiconductor device of the ninth embodiment, multiple amplifier circuits, such as two amplifier circuits, each being constituted by plural cells 20 connected in parallel with each other, are disposed on a common substrate 15 (FIG. 3). The conductive projection 54 (FIGS. 3 and 14A) is provided for each amplifier circuit. The two amplifier circuits are disposed adjacent to each other in the direction (x direction) perpendicular to the arranging direction of the cells 20.

Advantages of the ninth embodiment will be discussed below. In the ninth embodiment, two amplifier circuits can be operated as a differential amplifier, for example. The configuration similar to that of the semiconductor device of one of the first through seventh embodiments may be used for each of multiple amplifier circuits, thereby enhancing the breakdown resistance of the differential amplifier.

The above-described embodiments are only examples. The configurations described in different embodiments may partially be replaced by or combined with each other. Similar advantages obtained by similar configurations in plural embodiments are not repeated in the individual embodiments. The present disclosure is not restricted to the above-described embodiments. It is to be understood that variations, improvements, and combinations, for example, will be apparent to those skilled in the art.

What is claimed is:

1. A semiconductor device comprising:
a substrate; and
a plurality of cells side by side on the substrate in a first direction,
each of the plurality of cells including
a bipolar transistor including a collector layer, a base layer, and an emitter layer sequentially stacked on each other from the substrate,
at least one emitter electrode that is contained in the base layer as viewed from above and that is electrically connected to the emitter layer, and
a base electrode that is contained in the base layer as viewed from above and that is electrically connected to the base layer, wherein
the bipolar transistors of the plurality of cells are connected in parallel with each other, and
among the plurality of cells, breakdown resistance of at least one second cell of the plurality of cells, which is other than each of first cells of the plurality of cells each at a respective end of the plurality of cells, is higher than breakdown resistances of the first cells.

2. The semiconductor device according to claim 1, wherein
at least one of a shape of the base electrode of each of the plurality of cells in a plan view and a relative positional relationship between the at least one emitter electrode and the base electrode in a plan view is different for the first cells than for the at least one second cell.

3. The semiconductor device according to claim 1, wherein:
the at least one emitter electrode has an elongated shape in a second direction which is perpendicular to the first direction;
the base electrode includes a base finger elongated in the second direction;
regarding the at least one emitter electrode of each of the plurality of cells, two emitter electrodes are positioned in the first direction with a space therebetween, the base finger being sandwiched between the emitter electrodes; and
a width of the base finger of the at least one second cell in the first direction is wider than a width of the base finger of each of the first cells in the first direction.

4. The semiconductor device according to claim 1, wherein:
the at least one emitter electrode has an elongated shape in a second direction which is perpendicular to the first direction;
the base electrode includes a base finger elongated in the second direction;
regarding the at least one emitter electrode of each of the plurality of cells, two emitter electrodes are positioned in the first direction with a space therebetween, the base finger being sandwiched between the emitter electrodes; and
a gap between the base finger and each of the emitter electrodes is different for the first cells than for the at least one second cell, and the gap in the at least one second cell is wider than the gap in each of the first cells.

5. The semiconductor device according to claim 1, wherein:
the at least one emitter electrode has an elongated shape in a second direction which is perpendicular to the first direction;
the base electrode includes a base finger elongated in the second direction;
regarding the at least one emitter electrode, in each of the first cells, two emitter electrodes are positioned in the first direction with a space therebetween, the base finger being sandwiched between the emitter electrodes; and
regarding the at least one emitter electrode, one emitter is in the at least one second cell, the emitter electrode and the base finger being side by side in the first direction.

6. The semiconductor device according to claim 5, wherein:
the substrate includes a sub-collector layer on a front surface of the substrate, the collector layer of the bipolar transistor being on the sub-collector layer;
each of the plurality of cells includes at least one collector electrode, the at least one collector electrode being electrically connected to the collector layer via the sub-collector layer; and
the at least one second cell includes a plurality of second cells, and positional relationships among the base finger, the at least one emitter electrode, and the at least one collector electrode are different between the plurality of second cells.

7. The semiconductor device according to claim 1, wherein:
each of the plurality of cells further includes a base ballast resistor element connected to the base electrode; and
a resistance value of the base ballast resistor element of the at least one second cell is greater than a resistance value of the base ballast resistor element of each of the first cells.

8. The semiconductor device according to claim 1, wherein
a distance in the first direction between a centroid of the at least one emitter electrode of each of the first cells and a centroid of the at least one emitter electrode of each of the cells adjacent to one of the first cells is narrower than a distance in the first direction between a centroid of the at least one emitter electrode of one of the cells which is not one of the first cells and a centroid of the at least one emitter electrode of an adjacent one of the cells which is not one of the first cells.

9. The semiconductor device according to claim 1, further comprising:
a conductive projection that overlaps the plurality of cells as viewed from above and that is electrically connected to the emitter electrodes of the plurality of cells and that projects in a direction to separate from the substrate,
wherein the conductive projection has an elongated shape in the first direction as viewed from above, and a width of a portion of the conductive projection which overlaps the at least one second cell is wider than a width of a portion of the conductive projection which overlaps one of the first cells, as viewed from above.

10. The semiconductor device according to claim 1, further comprising:
a plurality of conductive projections that are side by side in the first direction in a cell distribution region where the plurality of cells are arranged from a cell at one end to a cell at the other end, as viewed from above, and that project in a direction to separate from the substrate, wherein
each of the plurality of conductive projections is electrically connected to a corresponding at least one emitter electrode among the emitter electrodes of the plurality of cells, and
a distribution density of the plurality of conductive projections becomes higher from end portions of the cell distribution region toward a center thereof in the first direction.

11. A semiconductor module comprising:
the semiconductor device according to claim 1; and
a module substrate on which the semiconductor device is flip-chip mounted.

12. The semiconductor device according to claim 2, wherein:
the at least one emitter electrode has an elongated shape in a second direction which is perpendicular to the first direction;
the base electrode includes a base finger elongated in the second direction;
regarding the at least one emitter electrode of each of the plurality of cells, two emitter electrodes are positioned in the first direction with a space therebetween, the base finger being sandwiched between the emitter electrodes; and
a width of the base finger of the at least one second cell in the first direction is wider than a width of the base finger of each of the first cells in the first direction.

13. The semiconductor device according to claim 2, wherein:
the at least one emitter electrode has an elongated shape in a second direction which is perpendicular to the first direction;
the base electrode includes a base finger elongated in the second direction;
regarding the at least one emitter electrode of each of the plurality of cells, two emitter electrodes are positioned in the first direction with a space therebetween, the base finger being sandwiched between the emitter electrodes; and
a gap between the base finger and each of the emitter electrodes is different for the first cells than for the at least one second cell, and the gap in the at least one second cell is wider than the gap in each of the first cells.

14. The semiconductor device according to claim 2, wherein:
the at least one emitter electrode has an elongated shape in a second direction which is perpendicular to the first direction;
the base electrode includes a base finger elongated in the second direction;
regarding the at least one emitter electrode, in each of the first cells, two emitter electrodes are positioned in the first direction with a space therebetween, the base finger being sandwiched between the emitter electrodes; and
regarding the at least one emitter electrode, one emitter electrode is in the at least one second cell, the emitter electrode and the base finger being side by side in the first direction.

15. The semiconductor device according to claim 2, wherein
a distance in the first direction between a centroid of the at least one emitter electrode of each of the first cells and a centroid of the at least one emitter electrode of each of the cells adjacent to one of the first cells is narrower than a distance in the first direction between a centroid of the at least one emitter electrode of one of the cells which is not one of the first cells and a centroid of the at least one emitter electrode of an adjacent one of the cells which is not one of the first cells.

16. The semiconductor device according to claim 3, wherein
a distance in the first direction between a centroid of the at least one emitter electrode of each of the first cells and a centroid of the at least one emitter electrode of each of the cells adjacent to one of the first cells is narrower than a distance in the first direction between a centroid of the at least one emitter electrode of one of the cells which is not one of the first cells and a centroid of the at least one emitter electrode of an adjacent one of the cells which is not one of the first cells.

17. The semiconductor device according to claim 2, further comprising:
a conductive projection that overlaps the plurality of cells as viewed from above and that is electrically connected to the emitter electrodes of the plurality of cells and that projects in a direction to separate from the substrate,
wherein the conductive projection has an elongated shape in the first direction as viewed from above, and a width of a portion of the conductive projection which overlaps the at least one second cell is wider than a width of a portion of the conductive projection which overlaps one of the first cells, as viewed from above.

18. The semiconductor device according to claim 2, further comprising:
a plurality of conductive projections that are side by side in the first direction in a cell distribution region where the plurality of cells are arranged from a cell at one end to a cell at the other end, as viewed from above, and that project in a direction to separate from the substrate, wherein
each of the plurality of conductive projections is electrically connected to a corresponding at least one emitter electrode among the emitter electrodes of the plurality of cells, and
a distribution density of the plurality of conductive projections becomes higher from end portions of the cell distribution region toward a center thereof in the first direction.

19. A semiconductor module comprising:
the semiconductor device according to claim 2; and
a module substrate on which the semiconductor device is flip-chip mounted.

20. A semiconductor module comprising:
a semiconductor device including a substrate, a plurality of cells side by side on the substrate in a first direction, and a conductive projection that is elongated in the first direction and that projects in a direction to separate from the substrate; and
a module substrate on which the semiconductor device is flip-chip mounted via the conductive projection,
each of the plurality of cells including
a bipolar transistor including a collector layer, a base layer, and an emitter layer sequentially stacked on each other from the substrate, and
at least one emitter electrode that is contained in the base layer as viewed from above and that is electrically connected to the emitter layer, wherein
the bipolar transistors of the plurality of cells are connected in parallel with each other,
the conductive projection overlaps the plurality of cells as viewed from above and is electrically connected to the emitter electrodes of the plurality of cells,
the module substrate includes a through-via that overlaps the conductive projection as viewed from above and that is elongated in the first direction and that is electrically connected to the conductive projection, and
the through-via includes an inward portion separated from both ends of the through-via in the first direction, a width of the inward portion being wider than a width of portions at both ends of the through-via.
